(19) United States
(12) Patent Application Publication
(10) Pub. No.: US 2010/0200394 A1
(43) Pub. Date: Aug. 12, 2010

(54) VACUUM THIN FILM FORMING APPARATUS

(75) Inventors: Yoshinori Nagamine, Tokyo (JP); Kanto Nakamura, Hopkins, MN (US); Koji Tsunekawa, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/719,920

(22) Filed: Mar. 9, 2010

Related U.S. Application Data
(63) Continuation of application No. PCT/JP2007/069461, filed on Oct. 4, 2007.

(51) Int. Cl. C23C 14/34

(52) U.S. Cl. 204/192.13; 204/298.03

(57) ABSTRACT

In order to automatically adjust a self-bias on a substrate to a constant value at all times and to form a high-quality insulating film with excellent process reproducibility, a vacuum thin film forming apparatus according to the present invention includes: a high-frequency sputtering device having a chamber, an evacuation means for evacuating the inside of the chamber, a gas introduction means for supplying gas into the chamber, a substrate holder provided within the chamber, and an electrode provided within the substrate holder; and at least one vacuum treatment chamber that can be selected from a group including a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber, and an ashing chamber, wherein the high-frequency sputtering device further includes a variable impedance mechanism electrically connected to the electrode for adjusting the potential of the substrate on the substrate holder.

### CROSS-REFERENCES TO RELATED APPLICATIONS

This application is a continuation application of International Application No. PCT/JP2007/069461, filed on Oct. 4, 2007, the entire contents of which are incorporated by reference herein.

### BACKGROUND OF THE INVENTION

1. Field of the Invention

The present invention relates to a magnetic reproduction head of a magnetic disc drive device, a storage element of a magnetic random access memory, and a magnetic sensor.

2. Related Background Art

A tunnel magnetoresistive thin film using an insulating film MgO as a tunnel barrier layer exhibits a very large magnetoresistive (change) ratio of 200% or more at ambient temperature, and therefore, its application to a reproduction magnetic head and to a storage element of MRAM is expected. There is a demand to reduce the element size for a higher resolution of a magnetic head and a higher integration of MRAM, and it is indispensable to reduce the junction resistance in order to ensure high-speed data transfer. Although it is possible to reduce the junction resistance by reducing the film thickness of the tunnel barrier layer MgO, there arises a problem that the magnetoresistive (change) ratio is also reduced at the same time. This may be attributed to the disordered crystal orientation in the initial state of the MgO film growth.

High-frequency sputtering has a problem that a substrate or a film during film formation is damaged because a bias voltage is applied easily to the structure in contact with plasma and inflow of positive ions from plasma accelerated by a potential difference from the plasma is unavoidable. Further, it should be taken into consideration that the substrate potential gradually changes as an insulating film is deposited on the substrate.

Patent document 1 discloses a technique capable of changing the potential of the substrate electrode with respect to the anode electrode by changing the resistance value of a variable resistor provided in the substrate electrode in a high-frequency sputtering device. Patent document 2 discloses a high-frequency sputtering device in which an electrode for controlling particles incident to the substrate is provided between the substrate and the target.

[Patent document 1] Japanese Unexamined Patent Publication (Kokai) No. 9-302464
[Patent document 2] Japanese Unexamined Patent Publication (Kokai) No. 6-179968

### SUMMARY OF THE INVENTION

In the conventional high-frequency sputtering method, it is difficult to ensure process reproducibility when forming an insulating film. As the insulating film is deposited on the shield and substrate holder, the potential changes with time, and therefore, it is not possible to keep constant the state of plasma and the magnitude of the self-bias on the substrate. Because of this, the quality differs for each substrate to be treated. In particular, when forming a metal thin film in the same film forming apparatus, the variation in quality is remarkable. In the case also where the substrate is electrically conductive, the magnitude of self-bias on the substrate changes with time as the insulting film is deposited on the substrate, resulting in instability of process. An object of the present invention is to automatically adjust the self-bias on a substrate to a fixed value at all times and to form a high-quality insulating film with excellent process reproducibility.

In order to achieve the above-described object, a vacuum thin film forming apparatus according to the present invention includes: a high-frequency sputtering device having a chamber, an evacuation means for evacuating an inside of the chamber, a gas introduction means for supplying gas into the chamber, a substrate holder provided within the chamber, and an electrode provided within the substrate holder; and at least one vacuum treatment chamber that can be selected from a group including a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber, and an ashing chamber, wherein the high-frequency sputtering device further includes a variable impedance mechanism electrically connected to the electrode for adjusting the potential of the substrate on the substrate holder.

According to the vacuum thin film forming apparatus of the present invention that controls the magnitude of the self-bias applied to the substrate with the variable impedance mechanism, it is possible to automatically adjust the self-bias on the substrate to a constant value at all times and to form a thin film of high quality with excellent process reproducibility.

### BRIEF DESCRIPTION OF THE DRAWINGS

FIG. 1 is a schematic diagram of a high-frequency sputtering device according to the present invention.

FIG. 2 is a diagram showing a method of forming a film using a high-frequency sputtering device according to the present invention.

FIG. 3 is a schematic diagram of a high-frequency sputtering device according to the present invention.

FIG. 4 is a schematic diagram of a vacuum thin film forming apparatus including a sputtering device according to the present invention.

FIG. 5 is a schematic diagram of a magnetoresistive thin film manufactured using a sputtering device according to the present invention.

FIG. 6 is a diagram showing the change of the junction resistance for the number of treated substrates manufactured using a sputtering device according to the present invention.

### EXPLANATIONS OF REFERENCE NUMERALS

1 high-frequency sputtering device
3 substrate holder
4 variable impedance mechanism
8 Vdc operation circuit
9 impedance control part
10 input detector
11 high-frequency power supply

### DESCRIPTION OF THE PREFERRED EMBODIMENTS

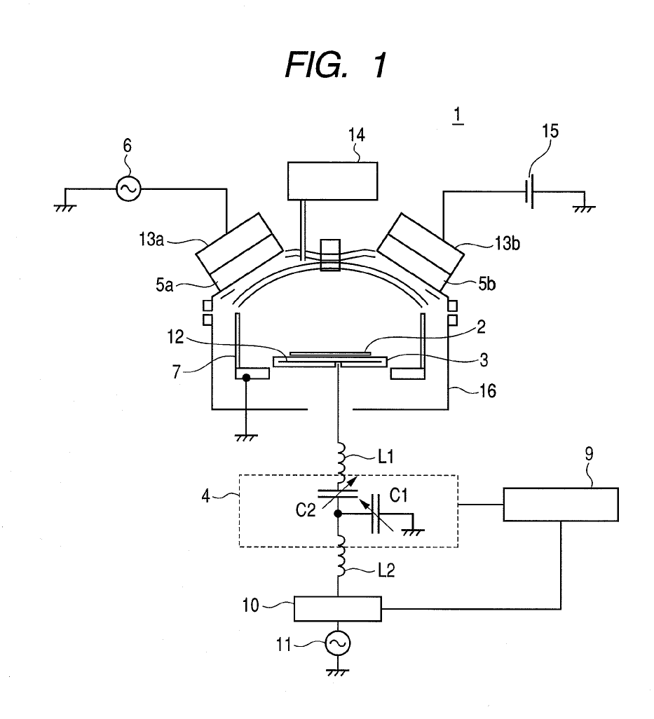

FIG. 1 is a schematic diagram of a high-frequency sputtering device 1 that exhibits the characteristics of the present invention. The configuration of the high-frequency sputtering device 1 to which the present invention can be applied will be described with reference to FIG. 1. The sputtering device 1 comprises sputtering cathodes 13a and 13b and each of the cathodes 13a and 13b includes a target mounting base. On the target mounting bases of the cathodes 13a and 13b, targets 5a and 5b are mounted, respectively. In the present embodiment, the target 5a is an insulator MgO target and the target 5b is a metal Ta target, however, it is possible for a user to appropriately change the targets by selection. The cathode 13a is connected to a high-frequency power supply 6 and the cathode 13b is connected to a DC power supply 15. The sputtering device 1 further includes a substrate holder 3 provided with a substrate mounting base for mounting a substrate 2 to be subjected to sputtering treatment, and a metal shield 7 that prevents sputtering particles discharged from a target 5 from sticking to a vacuum chamber 16. The respective target mounting bases of the cathodes 13a and 13b are installed so that their surfaces are not in parallel with the substrate mounting base of the substrate holder 3. Here, preferably, the diameters of the targets 5a and 5b are the same as or less than that of the substrate holder 3.

To an electrode 12 provided within the substrate holder 3, a variable impedance mechanism 4 is connected electrically. The variable impedance mechanism 4 includes an impedance matching circuit that combines a capacitor C and a coil L. Further, to the variable impedance mechanism 4, an impedance control part 9 and a high-frequency power supply 11, via an input detector 10, are connected. A gas, such as Ar, is supplied to the inside of the chamber 16 by a gas supply device 14. Although not shown schematically, the sputtering device 1 also includes a gas evacuation means for evacuating gas from the inside of the chamber 16.

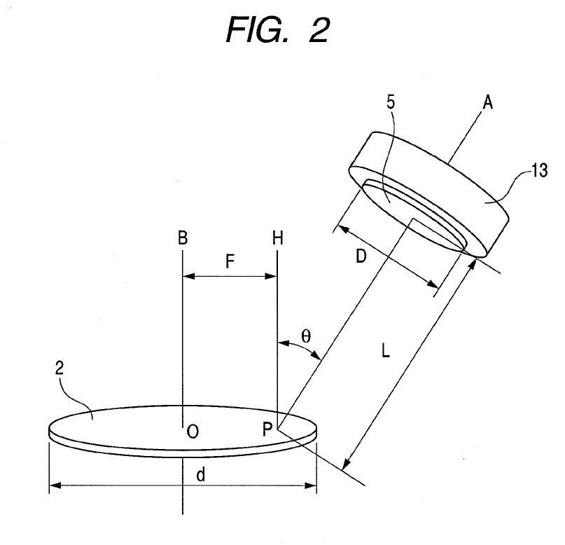

A method of forming a film using the high-frequency sputtering device 1 will be described with reference to FIG. 2. The high-frequency sputtering device 1 used in the present embodiment uses a method and is a device in which installation is made so that with respect to a normal H of the substrate 2 with a diameter d, a center axis line A of the target 5 with a diameter D mounted on a sputtering cathode 13 forms an angle θ, an offset distance F between the normal H and an intersection point P of the center axis line A and a plane that includes the substrate 2 is determined appropriately, a distance L between the target 5 and the substrate 2 is determined appropriately, and then, sputtering is performed, and its characteristic is that the values of the ratio between the diameter d of the substrate 2 and the diameter D of the target 5, the angle θ, and the distances F, L are set as follows. O represents the center point of the substrate 2 and B represents the center axis line of the substrate 2 that passes through the center point O.

The configuration is made so that the angle θ satisfies 15°≦?≦45°, the distance F 50 mm≦F≦400 mm, and the distance L 50 mm≦L≦800 mm, and in the following embodiment, θ is set to 30°, F to 250 mm, and L to 346.6 mm.

During film formation, the pressure in the vacuum chamber is maintained at about 10⁻⁷ Pa or less in order to form a film without mixing impurities into a thin film. When the Ar gas is introduced into the vacuum chamber by the gas supply device 14 and high-frequency power (13.56 MHz to 60 MHz) is applied to the cathode 13a by the high-frequency power supply 6, plasma is generated in the vacuum chamber 16. The Ar ion drawn out from the plasma collides with the target 5 and an MgO film is formed on the substrate 2 as sputter particles.

As described above, when sputtering is performed by applying high-frequency power to the insulator (MgO) target 5a, the substrate holder 3 at a floating potential is easily charged into a negative voltage by the generation of plasma. Because of this, a self-bias acts on the substrate 2, Ar positive ions from the plasma are accelerated by a potential difference between the positive potential of the plasma and the negative potential of the substrate and flow into the substrate 2, and thus the substrate 2 and the film during film formation are damaged. To cope with this problem, the sputtering device 1 according to the present invention includes the variable impedance mechanism 4.

A matching method using the variable impedance mechanism 4, which is an essential part of the present invention, will be described. To the electrode 12 provided within the substrate holder 3, the variable impedance mechanism 4 is connected and further, to the variable impedance mechanism 4, the high-frequency power supply 11 is connected. Small bias power is applied to the substrate holder 3 from the high-frequency power supply 11. Here, the bias voltage to be applied has power (4 W) as small as not to destroy the film during film formation.

The input detector 10 detects an input wave of the high-frequency power supply 11 and a reflected wave that is generated when matching is not established and power is not consumed, and inputs them to the impedance control part 9. The impedance control part 9 controls the variable impedance mechanism 4 based on the value of the input wave sent from the input detector and the value of the reflected wave from the electrode side. More specifically, the impedance control part 9 appropriately adjusts the ratio of capacitors C1, C2 and coils L1, L2 of an impedance matching circuit included in the variable impedance mechanism 4 and controls the variable impedance mechanism 4 so that the above-described reflected wave is not detected. In FIG. 1, only the capacitors C1, C2 and the coils L1, L2 are shown schematically, however, it is possible to appropriately select the capacitor C and the coil L or their combination by changing the design in accordance with an embodiment. When the reflected wave is not detected but only the input wave is detected, the variable impedance mechanism 4 determines that matching is established, that is, the self-bias on the substrate 2 is zero.

As described above, by applying bias power (power forward wave) to the substrate 2 and controlling the variable impedance mechanism 4 based on the detection of the reflected wave, it is possible to establish automatic matching. By adjusting the potential of the substrate 2 using the variable impedance 4, it is possible to optimize the incident energy of positive ions that flow in from the plasma.

If a metal film (for example, Ta) other than MgO is formed in the high-frequency sputtering device 1, not only the MgO film but also a Ta film sticks to the shield 7 or the inner wall of the vacuum chamber 16. The shield 7 referred to here is provided in order to prevent a film from sticking to the vacuum chamber 16 and can be replaced with another by a user of the device. The potential of the shield 7 changes with time depending on the number of films having been subjected to film formation treatment or the sticking of a plurality of films. Consequently, there arises a problem that the homogeneity and evenness of a film are lost, however, this problem can be solved by the use of the high-frequency sputtering device 1 comprising the variable impedance mechanism 4 of the present invention. Further, as insulating films are gradually deposited on the electrically conductive substrate 2, the potential of the substrate 2 changes with time. That is, since an insulator acts electrically as capacitance, the potential of the substrate on which the MgO film has been deposited changes. According to the present invention, it is also possible to always adjust the potential of a substrate to an optimum value.

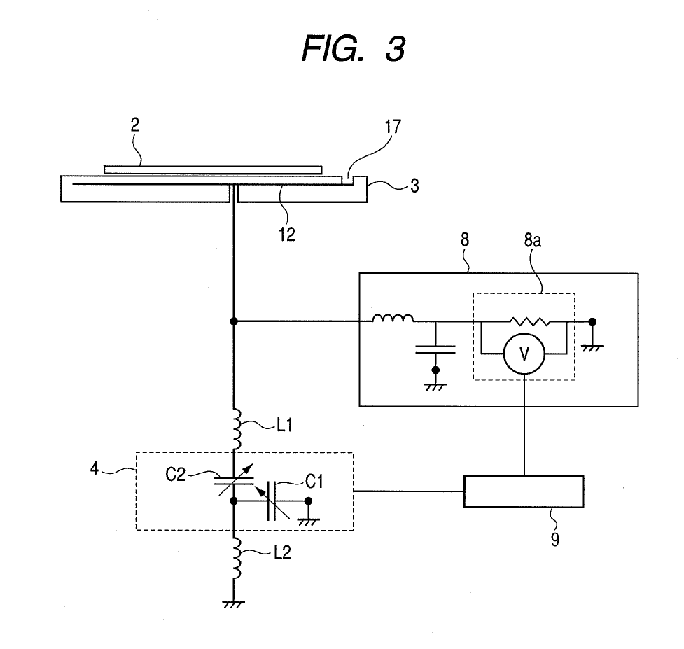

Next, FIG. 3 will be described. As shown in FIG. 3, within the substrate holder 3 on which the substrate 2 is mounted, the electrode 12 is provided. On the electrode 12, an incoming electron detection sensor (Vdc detection sensor) 17 that detects a current value by taking in incoming electrons from plasma is provided. Here, Vdc means a potential difference between the ground and the substrate. The high-frequency sputtering device in the present embodiment is provided with an operation circuit 8 including an operation part 8a that converts the current value detected by the discharge detection sensor 17 into Vdc, and the impedance control circuit part 9 that subjects the Vdc signal from the operation circuit 8 to operation processing and controls the impedance of the variable impedance mechanism 4. The variable impedance mechanism 4 includes an impedance matching circuit configured by combining the capacitor C and the coil L and is electrically connected to the electrode 12 provided within the substrate holder 3. Unlike the high-frequency sputtering device in the first embodiment, it is not necessary to use a high-frequency power supply.

The operation of the high-frequency sputtering device in the present embodiment will be described. The Vdc detection sensor 17 takes in incoming electrons that flow from plasma to the substrate 2 and detects a current value. From the detected high-frequency current value, only the direct current component is taken out by the LC circuit of the Vdc operation circuit 8 and Vdc is derived by the operation part 8a based on the Ohm's law. Based on Vdc calculated by the Vdc operation circuit 8a, the impedance control part 9 adjusts the variable impedance 4 so that Vdc becomes zero by appropriately adjusting the ratio between the capacitors C1, C2 and the coils L2, L2 constituting the variable impedance mechanism 4. In FIG. 3, only the capacitors C1, C2 and the coils L1, L2 are shown schematically, however, it is possible to appropriately change the design of selection and combination of the capacitor C and the coil L in accordance with the embodiment. If the substrate comes to have a large negative potential due to the change in impedance, the film structure is destroyed by incoming ions. On the contrary, if the potential of the substrate becomes too close to the ground, incoming electrons flow into the ground via the film and the film structure is destroyed by the current. An optimum impedance exists in between. As shown in the present embodiment, by changing the impedance by monitoring discharge parameters, such as Vdc, and providing automatic feedback, it is possible to always adjust the potential of the substrate to an optimized potential, the potential of the substrate changing with time as the insulating films are deposited gradually on the electrically conductive substrate 2 and the electrically conductive shield 7.

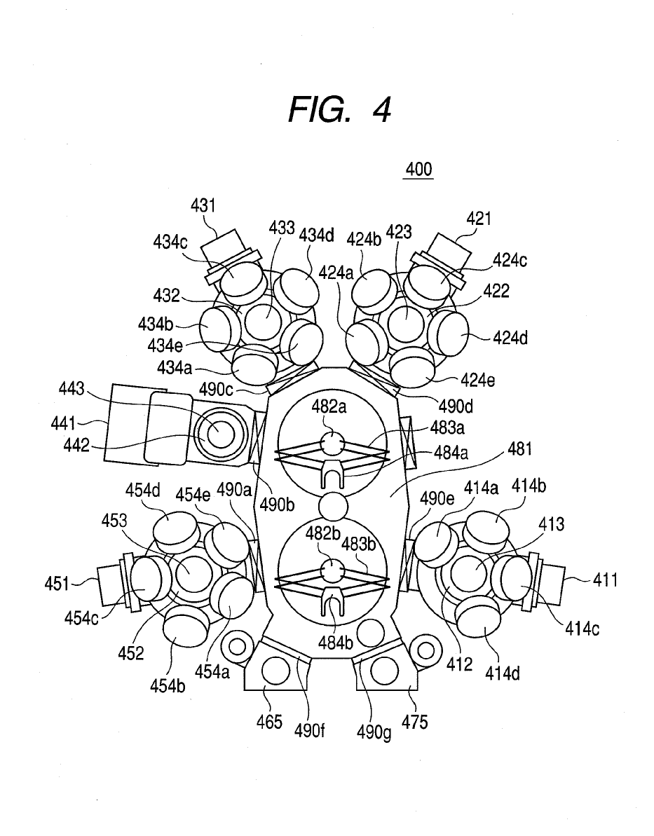

FIG. 4 shows a general configuration diagram of a vacuum thin film forming apparatus 400 for manufacturing a tunnel magnetoresistive thin film, including the sputtering device 1 of the present invention shown in FIG. 1. The vacuum thin film forming apparatus 400 is of cluster type and comprises a plurality of vacuum treatment chambers 411, 421, 431, 441 and 451. The vacuum treatment chamber includes at least a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber, and an ashing chamber, however, not limited to those. A vacuum substrate conveying chamber 481 comprising vacuum conveying robots 482a and 482b is installed in the center position and each vacuum treatment chamber is linked to each other via the vacuum conveying chamber. The vacuum conveying robots 482a and 482b comprise extensible/retractable arms 483a and 483b and hands 484a and 484b to mount the substrate. The proximal parts of the arms 483a and 483b are rotatably attached to the vacuum substrate conveying chamber 481. The vacuum substrate conveying chamber 481 of the vacuum thin film forming apparatus 400 shown in FIG. 4 is provided with load lock chambers 465 and 475. By means of the load lock chambers 465 and 475, a substrate to be treated is conveyed into the vacuum thin film forming apparatus 400 from outside and at the same time, a substrate having been subjected to treatment to form a magnetic multilayer film is conveyed out of the vacuum thin film forming apparatus 400 to outside. Between the vacuum substrate conveying chamber 481 and the respective load lock chambers 465 and 475, gate valves 490f and 490g separating both the chambers and capable of freely opening/closing when necessary are provided, respectively. The vacuum thin film forming apparatus 400 shown in FIG. 4 is provided with the four film forming chambers 411, 421, 431 and 451 and one pre-treatment chamber 441 around the vacuum substrate conveying chamber 481. Between the vacuum substrate conveying chamber 481 and the treatment chambers, gate valves 490a to 490e separating both the chambers and capable of freely opening/closing when necessary are provided, respectively. To each chamber, a vacuum evacuation means, a gas introduction means, an electric power supply means, etc., are annexed, however, those are not shown schematically. Each of the sputtering film forming chambers 411, 421, 431 and 451 of the vacuum thin film forming apparatus 400 shown in FIG. 4 is a film forming chamber to continuously form a plurality of films constituting a magnetoresistive element in the same chamber and one film forming chamber is provided with at least one target and sputtering cathode.

In the sputtering chamber 411, for a substrate 413 disposed on a substrate holder 412 in the center of the chamber bottom, a Ta target 414a, a MgO target 414b are disposed on the ceiling part respectively via a sputtering cathode, not shown schematically. As shown in FIG. 4, it is also possible to mount targets 414c and 414d on the sputtering chamber 411 and to appropriately use them in accordance with the embodiment. Between the vacuum substrate conveying chamber 481 and the sputtering chamber 411, the gate valve 490e separating both the chambers and capable of opening/closing when necessary is provided.

In the sputtering chamber 421, for a substrate 423 disposed on a substrate holder 422 in the center of the chamber bottom, a Ru target 424a, an IrMn target 424b, a 70CoFe target 424c, and a CoFeB target 424d are disposed on the ceiling part respectively via a sputtering cathode, not shown schematically. As shown in FIG. 4, it is also possible to mount a target 424e on the sputtering chamber 421 and to appropriately use it in accordance with the embodiment. Between the vacuum substrate conveying chamber 481 and the sputtering chamber 421, the gate valve 490d separating both the chambers and capable of freely opening/closing when necessary is provided.

In the sputtering chamber 431, for a substrate 433 disposed on a substrate holder 432 in the center of the chamber bottom, a Ta target 434a and a Cu target 434b are disposed respectively via a sputtering cathode, not shown schematically. As shown in FIG. 4, it is also possible to mount targets 434c, 434d and 434e on the sputtering chamber 431 and to appropriately use them in accordance with the embodiment. Between the vacuum substrate conveying chamber 481 and the sputtering chamber 431, the gate valve 490c separating both the chambers and capable of freely opening/closing when necessary is provided.

In the pre-treatment chamber 441, for a substrate 443 disposed on a substrate holder 442 in the center of the chamber bottom, pre-treatment, such as cleaning, of the substrate before film formation is performed by physical etching. Between the vacuum substrate conveying chamber 481 and the pre-treatment chamber 441, the gate valve 490b separating both the chambers and capable of freely opening/closing when necessary is provided.

In the sputtering chamber 451, for a substrate 453 disposed on a substrate holder 452 in the center of the chamber bottom, a CoFeB target 454a, a Ta target 454b, a Cu target 454c, and a Ru target 454d are disposed on the ceiling part respectively via a sputtering cathode, not shown schematically. As shown in FIG. 4, it is also possible to mount a target 454e on the sputtering chamber 451 and to appropriately use it in accordance with the embodiment. Between the vacuum substrate conveying chamber 481 and the sputtering chamber 451, the gate valve 490a separating both the chambers and capable of freely opening/closing when necessary is provided.

All of the chambers except the load lock chambers 465 and 475 are vacuum chambers at 1×10⁻⁶ Pa or less and the substrate is moved between each vacuum chamber by the vacuum conveying robots 482a and 482b in a vacuum. A substrate for forming a tunnel magnetoresistive thin film of spin valve type is disposed in the load lock chamber 465 or 475 set to the atmospheric pressure at first and after the load lock chamber 465 or 475 is evacuated, it is conveyed to a desired vacuum chamber by the vacuum conveying robots 482a and 482b.

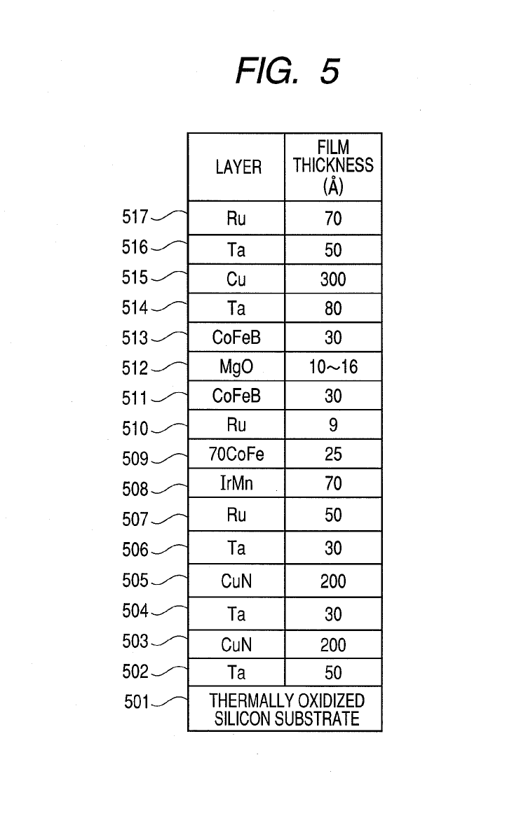

As shown in FIG. 5, the basic film structure is such that on a thermally oxidized substrate 501, a Ta film 502 (50 Å)/a CuN film 503 (200 Å)/a Ta film 504 (30 Å)/a CuN film 505 (200 Å)/a Ta film 506 (30 Å) are used as a lower electrode layer, a Ru film 507 (50 Å) as a seed layer, an IrMn film 508 (70 Å) as an antiferromagnetic layer, an antiferromagnetic combination including a CoFe film 509 (25 Å)/a Ru film 510 (9 Å)/a CoFeB film 511 (30 Å) as a magnetization pinned layer, and a MgO film 512 (10 to 16 Å) is used as a tunnel barrier layer. As a magnetization free layer, a CoFeB film 513 (30 Å) is formed. Finally, as an upper electrode, a stacked structure of a Ta film 514 (80 Å)/a Cu film 515 (300 Å)/a Ta film 516 (50 Å)/a Ru film 517 (70 Å) is used.

In order to efficiently form such a film structure, MgO for tunnel barrier layer and Ta for forming cleaning atmosphere are arranged in the sputtering chamber 411, Ru, IrMn, CoFe, CoFeB in the sputtering chamber 421, Ta, Cu in the sputtering chamber 431, and CoFeB, Ta, Cu, Ru in the sputtering chamber 451 as a sputtering target. First, the substrate is conveyed to the pre-treatment chamber 441 and the surface layer contaminated in the atmosphere is removed physically by about 2 nm by reverse sputter etching, and then, it is conveyed into the sputtering chamber 431 and a film including the Ta film 502, the CuN film 503, the Ta film 504, the CuN film 505, and the Ta film 506 is formed up to the lower electrode layer. After that, the substrate is moved to the sputtering chamber 421 and the seed layer including the Ru film 507 and the antiferromagnetic combination layer including the IrMn film 508, the CoFe film 509, the Ru film 510, and the CoFeB film 511 are formed and after the substrate is moved to the sputtering chamber 411, the tunnel barrier layer MgO film 512 (film thickness is 10 to 16 Å) is formed. Here, by forming the tunnel barrier layer MgO film 512 using the above-described oblique sputtering method, a very thin MgO film as thin as 10 to 16 Å can be obtained. After the tunnel barrier layer is formed, it is conveyed to the sputtering chamber 451, and the magnetization free layer including the CoFeB film 513 and the upper electrode layer including the Ta film 514, the Cu film 515, the Ta film 516 and the Ru film 517 are formed and then the substrate is returned to the load lock chamber 465 or 475.

The manufactured tunnel magnetoresistive thin film is put into an annealing furnace in a magnetic field and annealing treatment is performed at a desired temperature and for a desired period of time in a vacuum while a magnetic field parallel with one direction with an intensity of 8 kOe or more is applied. A magnetoresistive thin film completed in the above-described manner is shown in FIG. 5. When a magnetoresistive thin film, in which the tunnel barrier layer 512 is a MgO film, is formed using the vacuum thin film forming apparatus 400, it is possible to obtain a high-performance magnetoresistive thin film by forming the MgO tunnel barrier layer 512 using the high-frequency sputtering device 1 shown in FIG. 1.

It is possible to manufacture an MTJ device, such as a reproduction magnetic head, MRAM, and magnetic sensor, using the tunnel magnetoresistive thin film shown in FIG. 5.

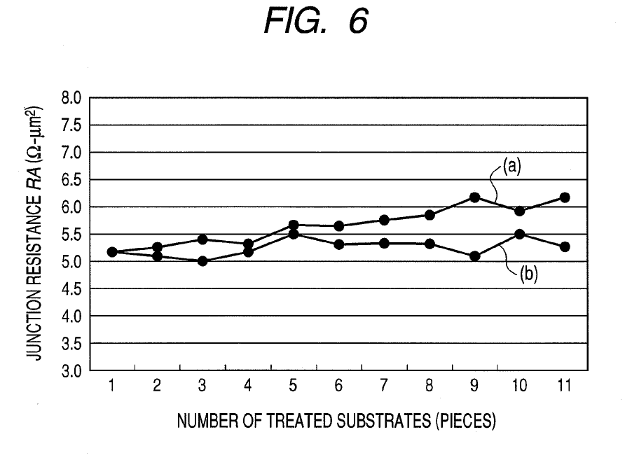

FIG. 6 is a diagram showing the change of the junction resistance RA (Ω·μm²) versus the number of treated substrates (pieces). In manufacturing the tunnel magnetoresistive thin film in FIG. 5 by using the vacuum thin film forming apparatus 400 and by forming the MgO tunnel barrier layer 512 in the high-frequency sputtering device 1, a) the reproducibility between substrates for the case where the capacitor ratio C1/C2 of the variable impedance mechanism 4 is fixed, and b) the reproducibility between substrates for the case where automatic matching is performed by applying very small bias power as small as 4 W and the C1/C2 ratio is controlled automatically, are compared. In the case a) where the C1/C2 ratio is fixed, RA increases as the number of treated substrates increases. This is because the MgO film thickness increases. On the other hand, In the case b) where the impedance is adjusted at all times in order to keep constant the substrate potential and the plasma state, the gradual increase of RA, such as that in the case of a), is not observed and the process reproducibility is improved. In the present embodiment, MgO is used as an insulating film and the examination of reproducibility is done by using RA of the tunnel magnetoresistive film, however, it can be thought that the present invention is effective alike in improving process reproducibility in the case of other insulating films.

The above-described embodiments are not intended to limit the scope of the present invention and it is possible to appropriately modify the above-described embodiments in order to realize the content of the subject matter of the scope of claims based on the teachings and the suggestions in the present embodiments.

1. A vacuum thin film forming apparatus comprising:
a high-frequency sputtering device including:
a chamber;
an evacuation means for evacuating an inside of the chamber;
a gas introduction means for supplying gas into the chamber;
a substrate holder provided within the chamber;
a target mounting base installed so as not to be parallel with a substrate mounting base of the substrate holder; and
an electrode provided within the substrate holder; and
at least one vacuum treatment chamber that can be selected from a group including a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber, and an ashing chamber,
wherein the high-frequency sputtering device further includes:
a variable impedence mechanism electrically connected to the electrode for adjusting the potential of the substrate on the substrate holder;
an incoming electron detection means provided on the electrode for detecting an incoming electron;
an operation circuit converting a current detected by the incoming electron detection means into a substrate potential; and
a control circuit performing operational processing on a substrate potential signal from the operation circuit to control the variable impedance mechanism.

2. A vacuum thin film forming apparatus according to claim 1, wherein the high-frequency sputtering device and the at least one vacuum treatment chamber are coupled to each other via a vacuum conveying chamber.

3.-5. (canceled)

6. A method of forming a thin film using the vacuum thin film forming apparatus according to claim 1, comprising:
a matching step using the high-frequency sputtering device; and
a vacuum treatment step of vacuum-treating a substrate in the at least one vacuum treatment device.

7. A high-frequency sputtering device comprising:
a chamber;
a gas introduction means for supplying gas into the chamber;
a plasma generation means for generating plasma of the gas within the chamber;
a substrate holder provided within the chamber;
an electrode provided within the substrate holder;
a variable impedance mechanism electrically connected to the electrode for adjusting the potential of the substrate on the substrate holder;
an incoming electron detection means provided on the electrode for detecting an incoming electron from the plasma;
an operation circuit converting a current detected by the incoming electron detection means into a potential difference between the ground and the substrate to the mounted on the substrate holder; and
a control circuit controlling the variable impedance mechanism so that the potential difference is zero based on the potential difference coverted in the operation circuit.
